(19) United States
(12) Patent Application Publication
(10) Pub. No.: US 2026/0171145 A1
(43) Pub. Date: Jun. 18, 2026

(54) MEMORY DEVICE INCLUDING ASSIST CIRCUIT FOR ADJUSTING VOLTAGE LEVEL OF WORDLINE

(71) Applicant: Samsung Electronics Co., Ltd., Suwon-si (KR)

(72) Inventors: Keonhee Cho, Suwon-si (KR); Hoon Kim, Suwon-si (KR)

(21) Appl. No.: 19/290,215

(22) Filed: Aug. 4, 2025

(30) Foreign Application Priority Data
Dec. 18, 2024 (KR) 10-2024-0189850

(51) Int. Cl. G11C 11/418; G11C 5/06; G11C 5/14

(52) U.S. Cl. CPC G11C 11/418; G11C 5/063; G11C 5/147

(57) ABSTRACT

A memory device includes a memory cell array including a plurality of memory cells; a row decoder selecting one of a plurality of wordlines connected to the plurality of memory cells based on an address received from a memory controller; and a wordline voltage generator providing a wordline voltage to a selected wordline. The wordline voltage generator includes a wordline driver outputting the wordline voltage which is reduced by a power supply voltage which varies based on a wordline driving voltage; a bump replica circuit generating a bump signal having a voltage level which increases or decreases in response to the power supply voltage; and a wordline voltage control circuit outputting the wordline driving voltage which increases or decreases complementarily to the bump signal.

### CROSS-REFERENCE TO RELATED APPLICATION(S)

This application claims priority under 35 U.S.C. § 119 to Korean Patent Application No. 10-2024-0189850 filed on Dec. 18, 2024, in the Korean Intellectual Property Office, the disclosures of which are incorporated by reference herein in their entireties.

### BACKGROUND

A semiconductor memory may be mainly classified as a volatile memory or a non-volatile memory. Read and write speeds of the volatile memory (for example, a DRAM or an SRAM) are fast, but the data stored in the volatile memory disappear when a power is turned off. In contrast, the non-volatile memory may retain data even when the power is turned off.

Memory cells of a static random access memory (SRAM) may have various disturb margins depending on the process variation. The SRAM may secure a disturb margin based on a worst process variation for reliability of an operation. In addition, the SRAM changing a power supply voltage during the operation may have a disturb margin changed depending on a level of the power supply voltage.

### SUMMARY

In general, the present disclosure is directed toward a memory device that includes an assist circuit for adaptively adjusting a voltage of driving a wordline by tracking a process variation according to a variable power supply voltage.

According to some implementations, the present disclosure is directed to a memory device that includes a memory cell array including a plurality of memory cells; a row decoder selecting one of a plurality of wordlines connected to the plurality of memory cells based on an address received from a memory controller; and a wordline voltage generator providing a wordline voltage to a selected wordline. The wordline voltage generator includes a wordline driver outputting the wordline voltage which is reduced by a power supply voltage which varies based on a wordline driving voltage; a bump replica circuit generating a bump signal having a voltage level which increases or decreases in response to the power supply voltage; and a wordline voltage control circuit outputting the wordline driving voltage which increases or decreases complementarily to the bump signal.

According to some implementations, the present disclosure is directed to a memory device that includes a memory cell array including a plurality of memory cells; a row decoder selecting one of a plurality of wordlines connected to the plurality of memory cells based on an address received from a memory controller; and a wordline voltage generator providing a wordline voltage to a selected wordline. The wordline voltage generator includes a wordline driver outputting the wordline voltage which is reduced by a power supply voltage which varies based on a wordline driving voltage; a first voltage control transistor including a source connected to the terminal of power supply voltage, a drain connected to a first node from which the wordline driving voltage is output and a gate to which a bump signal is input; a second voltage control transistor including a drain connected to the first node, a source connected to a second node and a gate to which a voltage adjustment enable signal is input; a third voltage control transistor including a drain and a gate connected to the second node, and a source connected to a third node; an interconnect resistor connected between the third node and a ground terminal; a first bump replica transistor including a drain connected to the terminal of power supply voltage, a source connected to a fourth node from which the bump signal is output and a gate to which the voltage adjustment enable signal is input; and a second bump replica transistor including a drain connected to the fourth node, a source connected to the ground terminal and a gate connected to the terminal of power supply voltage.

According to some implementations, the present disclosure is directed to a memory device that includes a memory cell array including a plurality of memory cells configured to operate at a first power supply voltage; an input/output circuit operating at a second power supply voltage lower than the first power supply voltage and performing a read or write operation of data through a plurality of bitlines each connected to the plurality of memory cells; a row decoder selecting one of a plurality of wordlines connected to the plurality of memory cells based on an address received from a memory controller; and a wordline voltage generator providing a wordline voltage to a selected wordline. The wordline voltage generator includes a wordline driver outputting the wordline voltage which is reduced by a power supply voltage which varies based on a wordline driving voltage; a bump replica circuit generating a bump signal having a voltage level which increases or decreases in response to a difference between the first power supply voltage and the second power supply voltage; and a wordline voltage control circuit outputting the wordline driving voltage which increases or decreases complementarily to the bump signal based on the first power supply voltage.

### BRIEF DESCRIPTION OF THE DRAWINGS

Example implementations will be more clearly understood from the following detailed explanation, taken in conjunction with the accompanying drawings.

FIG. 1 is a block diagram illustrating an example of a storage device according to some implementations.

FIG. 2 is a block diagram illustrating an example of the memory device illustrated in FIG. 1 according to some implementations.

FIG. 3 is a circuit diagram illustrating an example of a memory cell array illustrated in FIG. 2 according to some implementations.

FIG. 4 is a diagram illustrating an example of a first memory cell MC1 of FIG. 3 according to some implementations.

FIG. 5 is a diagram illustrating examples of wordlines connected to the memory cells of FIG. 3 and wordline drivers connected to the wordlines according to some implementations.

FIG. 6 is a diagram illustrating an example of the assist circuit of FIG. 5 according to some implementations.

FIG. 7 is a timing diagram illustrating an example of a wordline driving voltage according to an operation of the assist circuit of FIG. 6 according to some implementations.

FIG. 8 is a diagram illustrating an example of the assist circuit of FIG. 5 according to some implementations.

FIG. 9 is a diagram illustrating an example of the assist circuit of FIG. 5 according to some implementations.

FIG. 10 is a diagram illustrating an example of the assist circuit of FIG. 5 according to some implementations.

FIG. 11 is a diagram illustrating an example of a layout of the assist circuit of FIG. 8 according to some implementations.

FIG. 12 is a diagram illustrating an example of the assist circuit of FIG. 5 according to some implementations.

FIG. 13 is a diagram illustrating an example of the assist circuit of FIG. 5 according to some implementations.

FIG. 14 is a diagram illustrating an example of the assist circuit of FIG. 5 according to some implementations.

### DETAILED DESCRIPTION

Hereinafter, example implementations will be explained in detail with reference to the accompanying drawings.

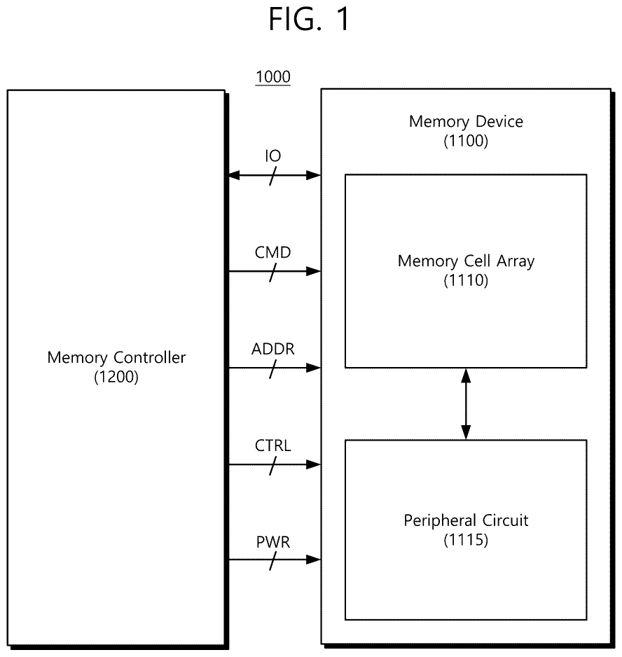

FIG. 1 is a block diagram illustrating an example of a storage device according to some implementations. In FIG. 1, a storage device 1000 may include a memory device 1100 and a memory controller 1200.

The memory device 1100 may receive input/output signals IO from the memory controller 1200 through input/output lines, receive control signals CTRL through control lines, and receive external supply power PWR through power lines. In addition, the memory device 1100 may receive commands CMD and addresses ADDR from the memory controller 1200. The storage device 1000 may store data in the memory device 1100 under control of the memory controller 1200.

The memory device 1100 may include a memory cell array 1110 and a peripheral circuit 1115. The memory cell array 1110 may have a planar 2D structure or a vertical 3D structure. The memory cell array may include a plurality of memory cells. The memory cell array 1110 may be positioned beside or over the peripheral circuit 1115

The peripheral circuit 1115 may include analog circuits and/or digital circuits required to store data in the memory cell array 1110 or read data stored in the memory cell array 1110. The peripheral circuit 1115 may receive the external supply power PWR through the power lines and generate internal powers of various levels based on the external supply power PWR.

The peripheral circuit 1115 may receive data from the memory controller 1200 through input/output lines. The peripheral circuit 1115 may store data in the memory cell array 1110 according to the control signals CTRL. In some implementations, the peripheral circuit 1115 may read data stored in the memory cell array 1110 and provide the read data to the memory controller 1200.

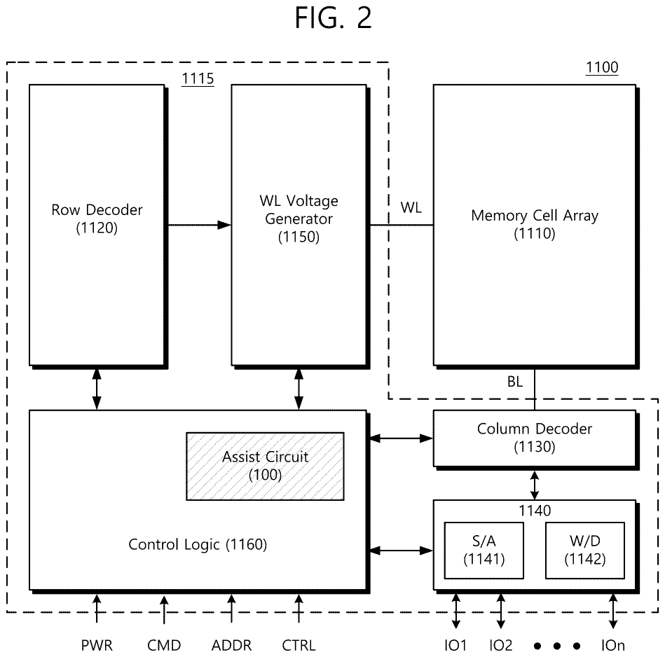

FIG. 2 is a block diagram illustrating an example of the memory device illustrated in FIG. 1 according to some implementations. In FIG. 2, the memory device 1100 may include a memory cell array 1110 and a peripheral circuit 1115. The peripheral circuit 1115 may include a row decoder 1120, a column decoder 1130, an input/output circuit 1140, a wordline voltage generator 1150, and/or control logic 1160.

The memory cell array 1110 may be connected to a plurality of wordlines. The memory cell array 1110 may be connected to a wordline voltage generator 1150 through the plurality of wordlines.

The row decoder 1120 may select a wordline during a write or read operation. The row decoder 1120 may select the wordline based on a row address included in an address ADDR.

The column decoder 1130 may be connected to the memory cell array 1110 through the plurality of bitlines. The column decoder 1130 may select one or more bitlines based on a column address included in the address ADDR.

The input/output circuit 1140 may be internally connected to the column decoder 1130 through data lines and externally connected to the memory controller 1200 (refer to FIG. 1) through input/output lines IO1 to IOn. The input/output circuit 1140 may receive write data from the memory controller 1200 during a write operation.

The input/output circuit 1140 may provide data read from the memory cell array 1110 to the memory controller 1200 during a read operation. The input/output circuit 1140 may output the data through the input/output lines IO1 to IOn. The number of input/output lines IO1 to IOn may be determined based on a kind of the storage device 1000.

The input/output circuit 1140 may include a plurality of sense amplifiers 1141 and a plurality of write drivers 1142. The plurality of sense amplifiers 1141 may read data from memory cells connected to a selected wordline during a read operation. The plurality of write drivers 1142 may store data to memory cells connected to a selected wordline during a write operation.

The wordline voltage generator 1150 may receive internal power from the control logic 1160 and generate a wordline voltage required to read or write data. The wordline voltage may be provided to a selected wordline through the row decoder 1120.

The control logic 1160 may control operations such as read and/or write of the memory device 1100 using commands CMD, addresses ADDR and control signals CTRL provided from the memory controller 1200. The addresses ADDR may include a row address for selecting one wordline and a column address for selecting one memory cell.

The control logic 1160 may include an assist circuit 100. The assist circuit 100 may provide a wordline driving voltage VDDWL to a plurality of wordline drivers included in the wordline voltage generator 1150 based on the power supply voltage VDD.

As the process is refined or the operating voltage is lowered, a read disturb phenomenon may occur in which writing is performed on a memory cell during a read operation or writing is performed on a memory cell that is not a writing target during a write operation. The assist circuit 100 may improve the read disturb phenomenon by lowering the wordline driving voltage VDDWL.

However, when the wordline driving voltage VDDWL is lowered, a write margin may decrease. Accordingly, in order to simultaneously achieve improvement of the lead disturb phenomenon and securing of the write margin, it is necessary to appropriately adjust the wordline driving voltage VDDWL according to fast/slow characteristics according to a temperature or process variation.

The control logic 1160 may change the power supply voltage VDD during operations by applying the dynamic voltage and frequency scaling (DVFS) scheme. The assist circuit 100 may adjust the wordline driving voltage VDDWL by tracking process variation of the memory cell array 1110 according to the variable power supply voltage VDD.

As an example, the memory device 1100 may use the same level of power supply voltage VDD in the memory cell array 1110 and the peripheral circuit 1115. As another example, the memory device 1100 may use different levels of power supply voltages in the memory cell array 1110 and the peripheral circuit 1115. The memory device 1100 may use a first power voltage VDDCE (for example, a memory cell power voltage) in the memory cell array 1110. The memory device 1100 may use a second power voltage VDDPE (for example, a peripheral circuit power voltage) in the peripheral circuit 1115.

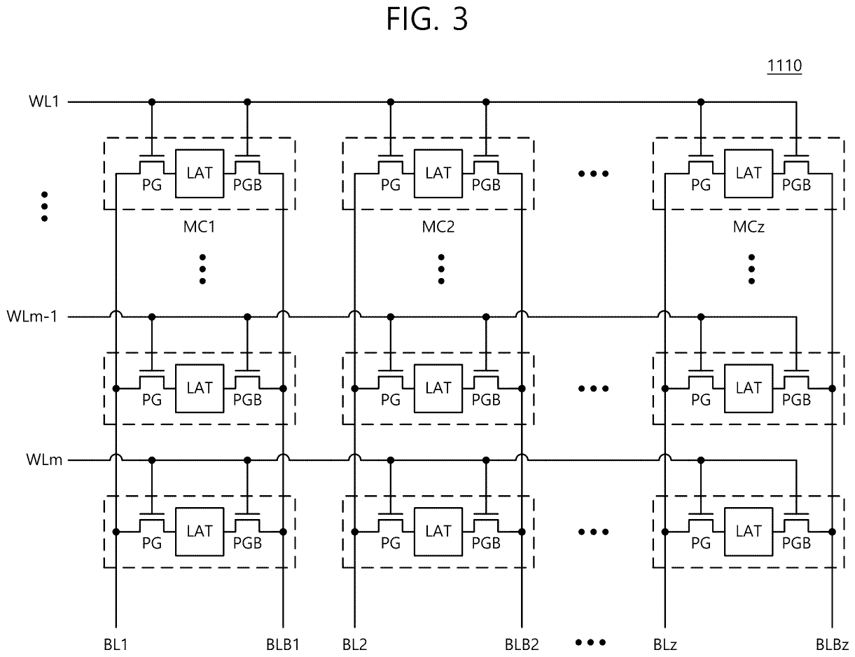

FIG. 3 is a circuit diagram illustrating an example of a memory cell array illustrated in FIG. 2 according to some implementations. In FIG. 3, the memory cell array 1110 may include a plurality of memory cells (for example, MC1 to MCz). Each memory cell may be a static random access memory cell.

The memory cell array 1110 may be connected to the row decoder 1120 and/or the wordline voltage generator 1150 through first to mth wordlines WL1 to WLm. The memory cell array 1110 may be connected to the column decoder 1130 through first to zth bitlines (BL1 to BLz, BLB1 to BLBz). As an example, BLB1 to BLBz may have complementary voltage levels with BL1 to BLz. For example, when BL1 is at a high level, BLB1 may be at a low level.

Each memory cell of the memory cell array 1110 may include a latch circuit LAT composed of inverters and pass gates PG and PGB. For example, the first memory cell MC1 may be connected to the first wordline WL1 and the first bitlines BL1 and BLB1. The first wordline WL1 may be connected to gates of first and second pass gates PG and PGB. The first bitlines BL1 and BLB1 may be connected to drains or sources of the first and second pass gates PG and PGB.

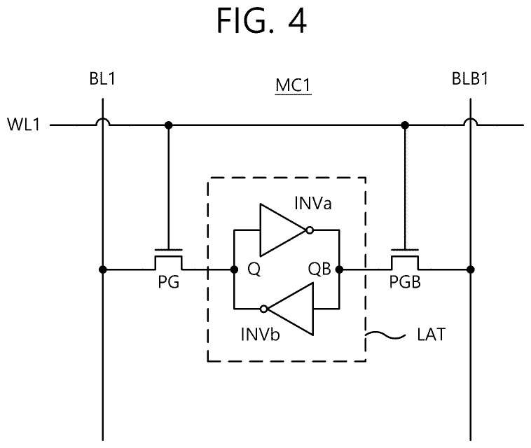

FIG. 4 is a diagram illustrating an example of a first memory cell MC1 of FIG. 3 according to some implementations. In FIG. 4, the first memory cell MC1 may include a latch circuit LAT and pass gates PG and PGB.

The first memory cell MC1 may store one bit. The first memory cell MC1 may include a first inverter INVa and a second inverter INVb. The latch circuit LAT may be composed of the first inverter INVa and the second inverter INVb. An output terminal of the first inverter INVa may be connected to an input terminal of the second inverter INVb. An output terminal of the second inverter INVb may be connected to the input terminal of the first inverter INVa.

The first pass gate PG may be connected between a first bitline BL1 and a first node Q to which the input terminal of the first inverter INVa is connected. In addition, the first pass gate PG may include a gate connected to a first wordline WL1. The second pass gate PGB may be connected between a first complementary bitline BLB1 and a second node QB connected to the input terminal of the second inverter INVb. Furthermore, the second pass gate PGB may include a gate connected to the first wordline WL1.

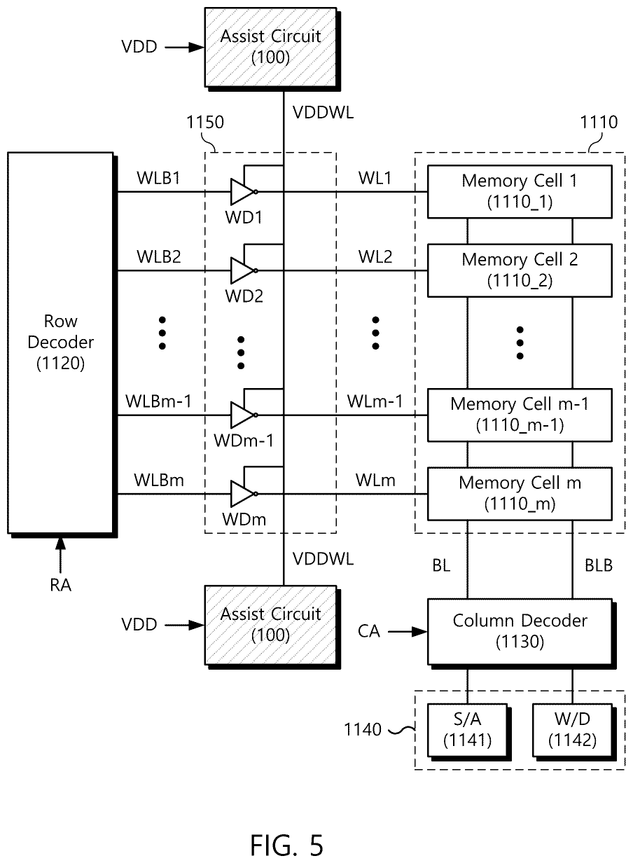

FIG. 5 is a diagram illustrating examples of wordlines connected to the memory cells of FIG. 3 and wordline drivers connected to the wordlines according to some implementations. In FIG. 5, the memory cell array 1110 may include a plurality of memory cells 1110_1 to 1110_m. For example, the plurality of memory cells 1110_1 to 1110_m may be memory cells connected to one bitline BL.

The plurality of memory cells 1110_1 to 1110_m may be connected to a plurality of wordlines WL1 to WLm, respectively. The plurality of wordlines WL1 to WLm may transmit a wordline voltage to a pass gate (PG or PGB of FIG. 3) of a connected memory cell.

The wordline voltage generator 1150 may include a plurality of wordline drivers WD1 to WDm. Output terminals of the plurality of wordline drivers WD1 to WDm may be respectively connected to a plurality of wordlines WL1 to WLm. In addition, input terminals of the plurality of wordline drivers WD1 to WDm may be respectively connected to a plurality of complementary wordlines WLB1 to WLBm.

The row decoder 1120 may select a wordline based on a row address RA included in the address ADDR of FIG. 2. For example, the row decoder 1120 may provide a wordline drive signal to a selected one of the plurality of complementary wordlines WLB1 to WLBm based on the row address RA. The wordline driver connected to the selected complementary wordline may invert the wordline drive signal based on the wordline drive voltage VDDWL and output the wordline drive signal to the selected wordline.

The column decoder 1130 may select one or more bitlines based on the column address CA included in the address ADDR of FIG. 2. During a write operation, the write driver 1142 may transmit data to the bitlines BL and BLB. During a read operation, the sense amplifier 1141 may detect voltages of the bitlines BL and BLB.

The control logic 1160 of FIG. 2 may include an assist circuit 100. The assist circuit 100 may provide a wordline driving voltage VDDWL to the plurality of wordline drivers WD1 to WDm based on a power supply voltage VDD.

As the process is refined or the operating voltage is lowered, a read disturb phenomenon may occur in which writing is performed on a memory cell during a read operation or writing is performed on a memory cell that is not a writing target during a write operation. The assist circuit 100 may improve the read disturb phenomenon by lowering the wordline driving voltage VDDWL.

However, when the wordline driving voltage VDDWL is lowered, a write margin may decrease. Accordingly, in order to simultaneously achieve the read disturb phenomenon improvement and the write margin securing, it is necessary to appropriately adjust the wordline driving voltage VDDWL according to the fast/slow characteristics based on a temperature or process variation.

The control logic 1160 may change the power supply voltage VDD during operations by applying the DVFS scheme. The assist circuit 100 may adjust the wordline driving voltage VDDWL by tracking the process variation of the memory cell array 1110 according to the variable power supply voltage VDD.

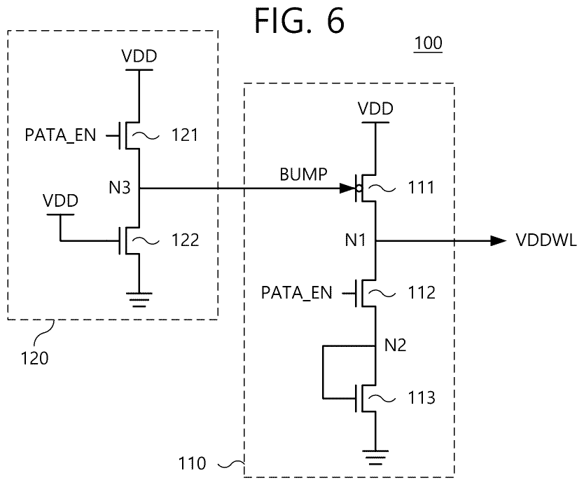

FIG. 6 is a diagram illustrating an example of the assist circuit of FIG. 5 according to some implementations. In FIG. 6, the assist circuit 100 may include a wordline voltage control circuit 110 and a bump replica circuit 120 (for example, a modified circuit of a process auto-tracking read assist (PATA)).

The wordline voltage control circuit 110 may include a first voltage control transistor 111, a second voltage control transistor 112 and a third voltage control transistor 113. As an example, the first voltage control transistor 111 may be implemented as a P-type transistor. The second voltage control transistor 112 and the third voltage control transistor 113 may be implemented as N-type transistors.

The first voltage control transistor 111 may include a source connected to a terminal of power supply voltage VDD, a drain connected to a first node N1 and a gate connected to a third node N3. The second voltage control transistor 112 may include a drain connected to the first node N1, a source connected to a second node N2 and a gate to which a voltage adjustment enable signal PATA_EN (for example, an enable signal for a process auto-tracking read assist (PATA)) is input. The third voltage control transistor 113 may include a drain and a gate connected to the second node N2, and a source connected to a ground terminal.

The bump replica circuit 120 may include a first bump replica transistor 121 and a second bump replica transistor 122. As an example, the first bump replica transistor 121 and the second bump replica transistor 122 may be implemented as N-type transistors.

The first bump replica transistor 121 may include a drain connected to the terminal of power supply voltage VDD, a source connected to the third node N3 and a gate to which the voltage adjustment enable signal PATA_EN is input. The second bump replica transistor 122 may include a drain connected to the third node N3, a source connected to the ground terminal and a gate connected to the terminal of power supply voltage VDD.

The wordline voltage control circuit 110 may track a global process corner through the second voltage control transistor 112 and the third voltage control transistor 113, and output a wordline driving voltage VDDWL lower than the power supply voltage VDD through the first node N1 according to the global process corner. Accordingly, the wordline voltage control circuit 110 may improve the read disturb margin of the memory cell (for example, MC1 of FIG. 3).

In addition, the wordline voltage control circuit 110 may receive a bump signal BUMP to the gate of the first voltage control transistor 111. The bump signal BUMP is a signal which replicates a bit-cell bump phenomenon occurring in a memory cell. Accordingly, the wordline voltage control circuit 110 may increase the wordline driving voltage VDDWL in response to the bump signal BUMP according to the DVFS operation of the power supply voltage VDD. Therefore, the wordline voltage control circuit 110 may improve the write margin together with the read disturb margin of the memory cell.

The bump replica circuit 120 may output the bump signal BUMP which replicates the bit-cell bump phenomenon occurring in the memory cell. The bump replica circuit 120 may generate the bump signal BUMP based on the voltage adjustment enable signal PATA_EN. The bump signal BUMP may be output through the third node N3.

When a level of the bump signal BUMP increases, a current flowing through the first voltage control transistor 111 may decrease and the wordline driving voltage VDDWL may be more lowered. When the level of the bump signal BUMP decreases, the current flowing through the first voltage control transistor 111 may increase and the wordline driving voltage VDDWL may be less lowered.

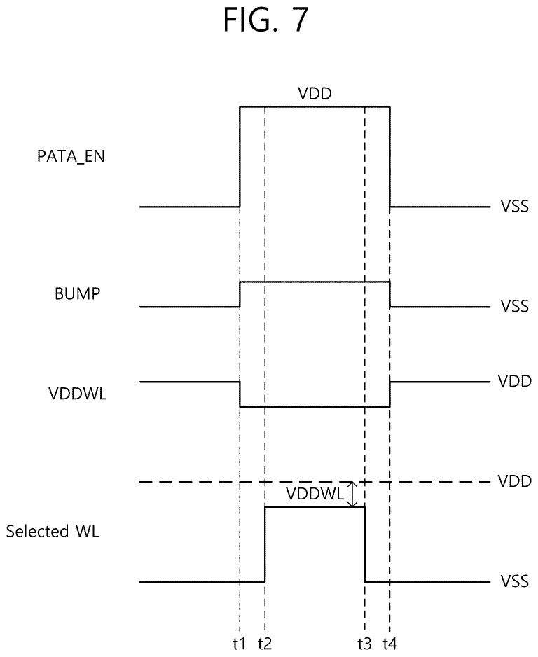

FIG. 7 is a timing diagram illustrating an example of a wordline driving voltage according to an operation of the assist circuit of FIG. 6 according to some implementations. In FIGS. 6 and 7, the assist circuit 100 may adaptively output the wordline driving voltage VDDWL according to a change in the power supply voltage VDD.

At a first time point t1, the voltage adjustment enable signal PATA_EN may be applied to the gate of the second voltage control transistor 112 and the gate of the first bump replica transistor 121. The voltage adjustment enable signal PATA_EN may be generated based on the power supply voltage VDD by the control logic 1160 of FIG. 2. The voltage adjustment enable signal PATA_EN may be activated at the first time point t1 before a specified time has elapsed to a second time point t2 at which the wordline voltage is supplied to a selected wordline. The voltage adjustment enable signal PATA_EN may be deactivated at a fourth time point t4 after a specified time has elapsed from a third time point t3 at which the wordline voltage is cut off to the selected wordline.

When the voltage adjustment enable signal PATA_EN is activated, the bump signal BUMP replicating a bit-cell bump phenomenon may be output from the third node N3 according to a resistance ratio of the first bump replica transistor 121 and the second bump replica transistor 122.

When the bump signal BUMP is applied to the gate of the first voltage control transistor 111, a resistance of the first voltage control transistor 111 may increase based on a size of the bump signal BUMP and the wordline driving voltage VDDWL may be generated complementarily to the bump signal BUMP.

Between the second time point t2 and the third time point t3, a wordline voltage may be supplied to the selected wordline according to a selection of the row decoder 1120. At this time, the wordline voltage may be formed lower than the power supply voltage VDD by the wordline driving voltage VDDWL. The assist circuit 100 may determine the wordline driving voltage VDDWL based on the global process corner of the memory cell. In addition, the assist circuit 100 may change a size of the wordline driving voltage VDDWL according to the change in the power supply voltage VDD.

At the fourth time point t4 after a specified time has elapsed from the third time point t3, the control logic 1160 may deactivate the voltage adjustment enable signal PATA_EN.

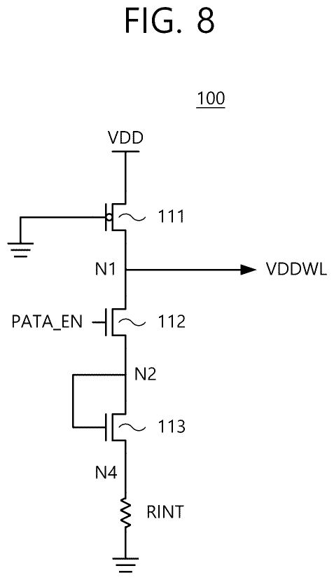

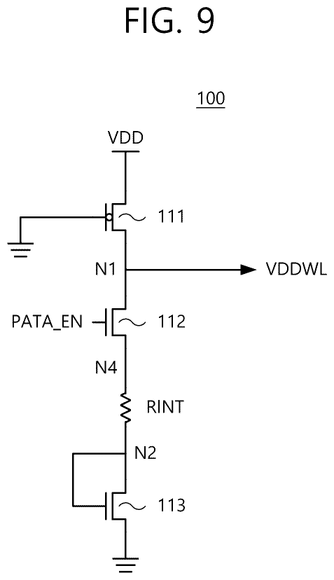

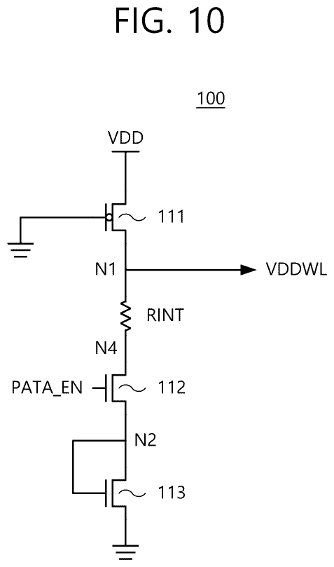

FIG. 8 is a diagram illustrating an example of the assist circuit of FIG. 5 according to some implementations. FIG. 9 is a diagram illustrating an example of the assist circuit of FIG. 5 according to some implementations. FIG. 10 is a diagram illustrating an example of the assist circuit of FIG. 5 according to some implementations.

In FIGS. 8 to 10, the assist circuit 100 may include a first voltage control transistor 111, a second voltage control transistor 112, a third voltage control transistor 113 and an interconnect resistor RINT. As an example, the first voltage control transistor 111 may be implemented as a P-type transistor. The second voltage control transistor 112 and the third voltage control transistor 113 may be implemented as N-type transistors.

In the assist circuit 100, the first voltage control transistor 111, the second voltage control transistor 112 and the third voltage control transistor 113 may have effective resistances which vary depending on the size of the power supply voltage VDD. The interconnect resistor RINT may have a fixed resistance value regardless of the size of the power supply voltage VDD. The wordline driving voltage VDDWL may be output from a first node N1 between the first voltage control transistor 111 and the second voltage control transistor 112. Accordingly, the wordline driving voltage VDDWL may be determined according to a ratio of the interconnect resistor RINT to effective resistances of the first voltage control transistor 111, the second voltage control transistor 112 and the third voltage control transistor 113.

When the level of the power supply voltage VDD decreases, the effective resistances of the first voltage control transistor 111, the second voltage control transistor 112 and the third voltage control transistor 113 may increase exponentially and become much larger than the interconnect resistor RINT. In some implementations, the wordline driving voltage VDDWL may be determined by the ratio between the effective resistances of the first voltage control transistor 111, the second voltage control transistor 112 and the third voltage control transistor 113.

When the level of the power supply voltage VDD increases, the effective resistances of the first voltage control transistor 111, the second voltage control transistor 112 and the third voltage control transistor 113 may decrease exponentially and become smaller than the interconnect resistor RINT. In some implementations, the wordline driving voltage VDDWL may be determined by the interconnect resistor RINT.

Accordingly, when the level of the power supply voltage VDD decreases, the ratio of the effective resistance of the first voltage control transistor 111 may increase, so that the wordline driving voltage VDDWL may decrease. When the level of the power supply voltage VDD increases, the ratio of the resistance of the discharge path (for example, interconnect resistor RINT) may increase, so that the wordline driving voltage VDDWL may increase. Accordingly, the assist circuit 100 may adjust the wordline driving voltage VDDWL according to the global process corner.

In FIG. 8, the first voltage control transistor 111 may include a source connected to the terminal of power supply voltage VDD, a drain connected to the first node N1 and a gate connected to the ground terminal. The second voltage control transistor 112 may include a drain connected to the first node N1, a source connected to the second node N2 and a gate to which the voltage adjustment enable signal PATA_EN is input. The third voltage control transistor 113 may include a drain and a gate connected to the second node N2, and a source connected to the fourth node N4. The interconnect resistor RINT may be connected between the fourth node N4 and the ground terminal.

In FIG. 9, the first voltage control transistor 111 may include a source connected to the terminal of power supply voltage VDD, a drain connected to the first node N1 and a gate connected to the ground terminal. The second voltage control transistor 112 may include a drain connected to the first node N1, a source connected to the fourth node N4 and a gate to which the voltage adjustment enable signal PATA_EN is input. The interconnect resistor RINT may be connected between the fourth node N4 and the second node N2. The third voltage control transistor 113 may include a drain and a gate connected to the second node N2, and a source connected to the ground terminal.

In FIG. 10, the first voltage control transistor 111 may include a source connected to the terminal of power supply voltage VDD, a drain connected to the first node N1 and a gate connected to the ground terminal. The interconnect resistor RINT may be connected between the first node N1 and the fourth node N4. The second voltage control transistor 112 may include a drain connected to the fourth node N4, a source connected to the second node N2 and a gate to which the voltage adjustment enable signal PATA_EN is input. The third voltage control transistor 113 may include a drain and a gate connected to the second node N2, and a source connected to the ground terminal.

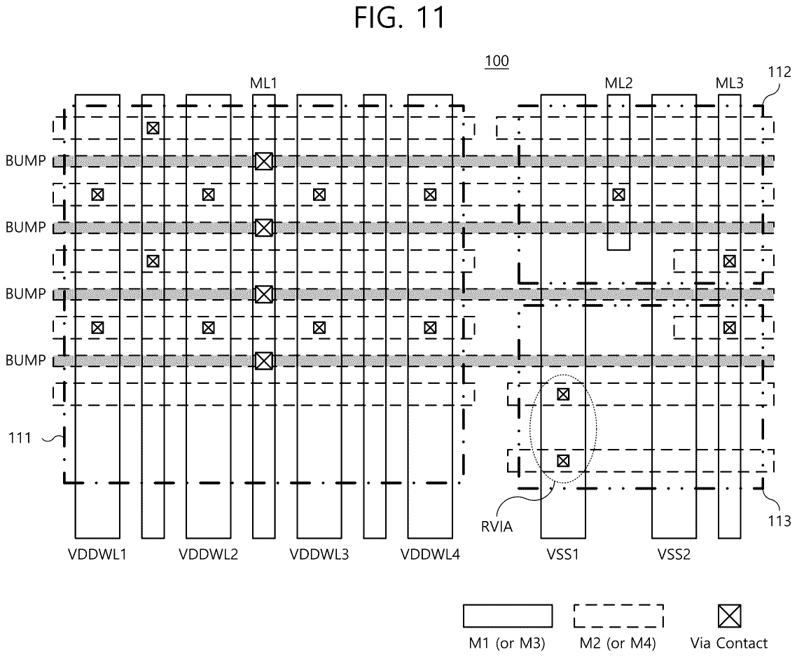

FIG. 11 is a diagram illustrating an example of a layout of the assist circuit of FIG. 8 according to some implementations. In FIG. 8 and FIG. 11, the assist circuit 100 may implement an interconnect resistor RINT by a via contact. In FIG. 11, a solid line may be an M1 layer or an M3 layer, and a dotted line may be an M2 layer or an M4 layer.

A memory device (for example, the memory device 1100 of FIG. 2) may connect different metal layers using via contacts in a semiconductor chip. A via contact process may be performed in following steps. First, an interlayer insulating layer may be formed. An insulating layer may be formed between metal layers to prevent electrical interference. Next, a via hole may be formed. A small hole may be made in the insulating layer to create a via hole. Next, a metal may be deposited. The via hole may be filled with metal to electrically connect the via contact. For example, tungsten W or copper Cu may be used as the metal. Next, a planarization CMP operation may be performed. After the metal is filled, the surface may be made flat and the next process may be prepared.

The first voltage control transistor 111 may receive a bump signal BUMP through a first metal line ML1 and via contacts. In the first voltage control transistor 111, a plurality of driving voltage lines VDDWL1 to VDDWL4 may be connected in parallel and output a wordline driving voltage VDDWL to reduce resistance.

A size of the interconnect resistor RINT may be implemented through via resistance RVIA. When the via resistance RVIA is connected in parallel to a plurality of ground lines VSS1 and VSS2, the interconnect resistor RINT may decrease. Alternatively or additionally, when the via resistance RVIA is omitted from the second ground line VSS2 and the via resistance RVIA is connected to only first ground line VSS1, the interconnect resistor RINT may increase.

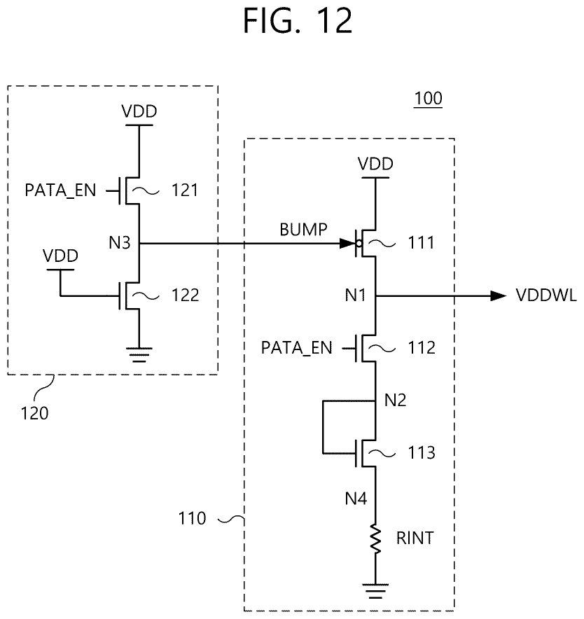

FIG. 12 is a diagram illustrating an example of the assist circuit of FIG. 5 according to some implementations. In FIG. 12, the assist circuit 100 may include a wordline voltage control circuit 110 and a bump replica circuit 120.

The wordline voltage control circuit 110 may include a first voltage control transistor 111, a second voltage control transistor 112 and a third voltage control transistor 113. As an example, the first voltage control transistor 111 may be implemented as a P-type transistor. The second voltage control transistor 112 and the third voltage control transistor 113 may be implemented as N-type transistors.

The first voltage control transistor 111 may include a source connected to a terminal of power supply voltage VDD, a drain connected to a first node N1 and a gate connected to a ground terminal. The second voltage control transistor 112 may include a drain connected to the first node N1, a source connected to a second node N2 and a gate to which a voltage adjustment enable signal PATA_EN is input. The third voltage control transistor 113 may include a drain and a gate connected to the second node N2, and a source connected to a fourth node N4. An interconnect resistor RINT may be connected between the fourth node N4 and the ground terminal. However, as shown in FIGS. 8 to 10, the interconnect resistor RINT may be arranged in series with the voltage control transistors (for example, the first voltage control transistor 111, the second voltage control transistor 112 and the third voltage control transistor 113) at various locations between the first node N1 and the ground terminal.

The bump replica circuit 120 may include a first bump replica transistor 121 and a second bump replica transistor 122. As an example, the first bump replica transistor 121 and the second bump replica transistor 122 may be implemented as N-type transistors.

The first bump replica transistor 121 may include a drain connected to the terminal of power supply voltage VDD, a source connected to a third node N3 and a gate to which the voltage adjustment enable signal PATA_EN is input. The second bump replica transistor 122 may include a drain connected to the third node N3, a source connected to the ground terminal and a gate connected to the terminal of power supply voltage VDD.

In FIG. 6, when a level of bump signal BUMP increases, a current flowing through the first voltage control transistor 111 may decrease and the wordline driving voltage VDDWL may be more lowered. When the level of bump signal BUMP decreases, a current flowing through the first voltage control transistor 111 may increase and the wordline driving voltage VDDWL may be less lowered.

In addition, in FIGS. 8 to 10, when the level of power supply voltage VDD decreases through the interconnect resistor RINT, a ratio of the effective resistance of the first voltage control transistor 111 may increase and the wordline driving voltage VDDWL may be lowered. When the level of power supply voltage VDD increases, a resistance ratio of the discharge path (for example, the interconnect resistor RINT) may increase and the wordline driving voltage VDDWL may increase.

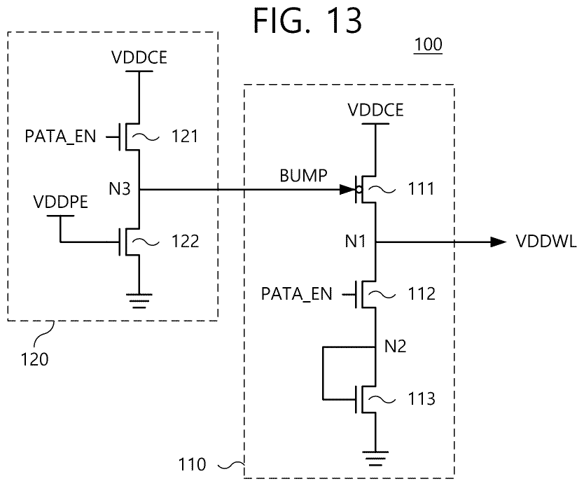

FIG. 13 is a diagram illustrating an example of the assist circuit of FIG. 5 according to some implementations. In FIG. 13, the assist circuit 100 may include a wordline voltage control circuit 110 and a bump replica circuit 120. In FIG. 13, the memory device 1100 may use different levels of power voltages in the memory cell array 1110 and the peripheral circuit 1115. For example, the memory device 1100 may use a first power voltage VDDCE in the memory cell array 1110. The memory device 1100 may use a second power voltage VDDPE in the peripheral circuit 1115.

As an example, the first power voltage VDDCE may be set to a higher level than the second power voltage VDDPE. Accordingly, when the second power supply voltage VDDPE is varied according to the DVFS scheme and a difference between the first power supply voltage VDDCE and the second power supply voltage VDDPE increases, the disturb margin of the memory cell may decrease.

The wordline voltage control circuit 110 may include a first voltage control transistor 111, a second voltage control transistor 112 and a third voltage control transistor 113. It may be configured in the same manner as the wordline voltage control circuit 110 of FIG. 6. A source of the first voltage control transistor 111 may be connected to the terminal of first power supply voltage VDDCE.

The bump replica circuit 120 may include a first bump replica transistor 121 and a second bump replica transistor 122. As an example, the first bump replica transistor 121 and the second bump replica transistor 122 may be implemented as N-type transistors.

The first bump replica transistor 121 may include a drain connected to the terminal of first power supply voltage VDDCE, a source connected to a third node N3 and a gate to which a voltage adjustment enable signal PATA_EN is input. The second bump replica transistor 122 may include a drain connected to the third node N3, a source connected to a ground terminal and a gate connected to the terminal of second power supply voltage VDDPE.

The second bump replica transistor 122 may be driven by the second power supply voltage VDDPE and may be driven weaker than the first bump replica transistor 121. Accordingly, a bump signal BUMP of FIG. 13 may rise less than the bump signal BUMP of FIG. 6. Accordingly, even if the first power supply voltage VDDCE is different from the second power supply voltage VDDPE, the bump replica circuit 120 may secure a disturb margin by generating the bump signal BUMP based on the difference between the first power supply voltage VDDCE and the second power supply voltage VDDPE.

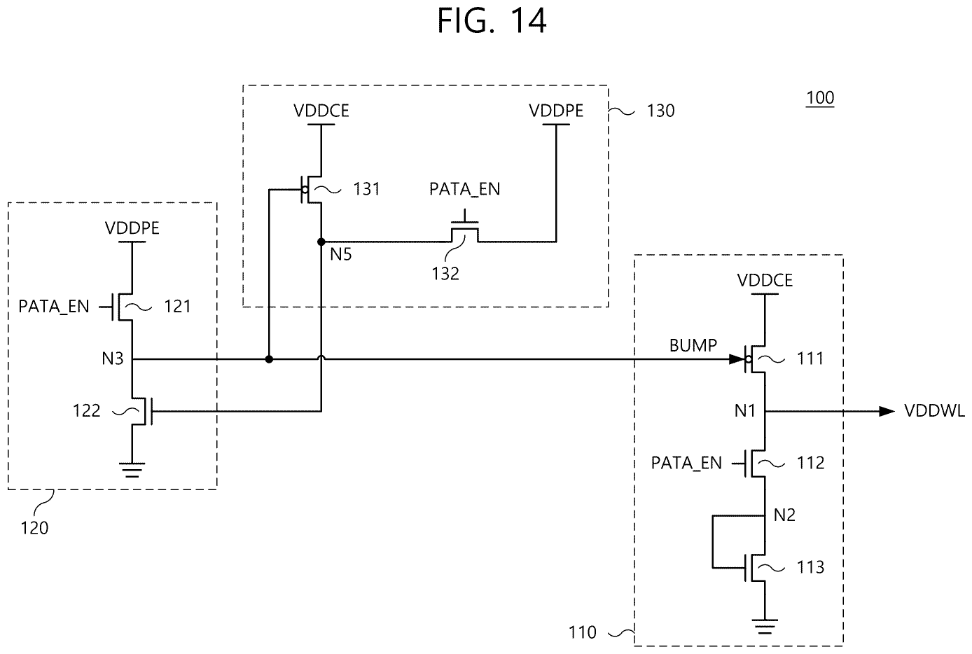

FIG. 14 is a diagram illustrating an example of the assist circuit of FIG. 5 according to some implementations. In FIG. 14, the assist circuit 100 may include a wordline voltage control circuit 110, a bump replica circuit 120 and a bump control circuit 130. In FIG. 14, the memory device 1100 may use different levels of power voltages in the memory cell array 1110 and the peripheral circuit 1115. For example, the memory device 1100 may use a first power voltage VDDCE in the memory cell array 1110. The memory device 1100 may use a second power voltage VDDPE in the peripheral circuit 1115.

As an example, the first power voltage VDDCE may be set to a higher level than the second power voltage VDDPE. Accordingly, when the second power supply voltage VDDPE is varied according to the DVFS scheme and a difference between the first power supply voltage VDDCE and the second power supply voltage VDDPE increases, the disturb margin of the memory cell may decrease.

The wordline voltage control circuit 110 may include a first voltage control transistor 111, a second voltage control transistor 112 and a third voltage control transistor 113. It may be configured in the same manner as the wordline voltage control circuit 110 of FIG. 13. A source of the first voltage control transistor 111 may be connected to the terminal of first power supply voltage VDDCE.

The bump replica circuit 120 may include a first bump replica transistor 121 and a second bump replica transistor 122. As an example, the first bump replica transistor 121 and the second bump replica transistor 122 may be implemented as N-type transistors.

The first bump replica transistor 121 may include a drain connected to the terminal of second power supply voltage VDDPE, a source connected to a third node N3 and a gate to which a voltage adjustment enable signal PATA_EN is input. The second bump replica transistor 122 may include a drain connected to the third node N3, a source connected to a ground terminal and a gate connected to a fifth node N5.

The bump control circuit 130 may include a first bump control transistor 131 and a second bump control transistor 132. As an example, the first bump control transistor 131 may be implemented as a P-type transistor. The second bump control transistor 132 may be implemented as an N-type transistor.

The first bump control transistor 131 may include a source connected to the terminal of first power supply voltage VDDCE, a drain connected to a fifth node N5 and a gate connected to a third node N3. The second bump control transistor 132 may include a drain connected to the fifth node N5, a source connected to the terminal of second power supply voltage VDDPE and a gate to which a voltage adjustment enable signal PATA_EN is input.

The bump replica circuit 120 may output a bump signal BUMP having a lower level than that of the bump replica circuit 120 of FIG. 13 based on the second power supply voltage VDDPE. In addition, the second bump replica transistor 122 may be driven by a voltage level of the fifth node N5. The voltage level of the fifth node N5 may be controlled by the second bump control transistor 132. The second bump control transistor 132 may be turned on according to a difference between the voltage adjustment enable signal PATA_EN generated based on the first power supply voltage VDDCE and the second power supply voltage VDDPE.

Accordingly, the second bump replica transistor 122 may be driven when a difference between the first power supply voltage VDDCE and the second power supply voltage VDDPE increases by a specified voltage or more. The second bump replica transistor 122 of FIG. 14 may operate less sensitively to the second power supply voltage VDDPE than the second bump replica transistor 122 of FIG. 13.

According to the present disclosure, it may be possible to simultaneously optimize a read disturb margin and a write margin of the memory device according to a variable power voltage.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a memory cell array including a plurality of memory cells;
a row decoder configured to select one of a plurality of wordlines connected to the plurality of memory cells based on an address received from a memory controller; and
a wordline voltage generator configured to provide a wordline voltage to the selected one of the plurality of wordlines,
wherein the wordline voltage generator comprises:
a wordline driver configured to output the wordline voltage, the wordline voltage being configured to be reduced by a power supply voltage, the power supply voltage being configured to vary based on a wordline driving voltage;
a bump replica circuit configured to generate a bump signal having a voltage level that is configured to increase or decrease in response to the power supply voltage; and
a wordline voltage control circuit configured to output the wordline driving voltage that is configured to increase or decrease complementarily to the bump signal.

2. The memory device of claim 1, wherein the wordline voltage control circuit comprises:
a first voltage control transistor including:
a source configured to receive the power supply voltage,
a drain connected to a first node configured to output the wordline driving voltage, and
a gate configured to receive the bump signal;
a second voltage control transistor including a drain connected to the first node, a source connected to a second node, and a gate configured to receive a voltage adjustment enable signal;
a third voltage control transistor including a drain and a gate connected to the second node, and a source connected to a ground terminal, and
wherein the bump replica circuit comprises:
a first bump replica transistor including a drain configured to receive the power supply voltage, a source connected to a third node configured to output the bump signal, and a gate configured to receive the voltage adjustment enable signal; and
a second bump replica transistor including a drain connected to the third node, a source connected to the ground terminal, and a gate configured to receive the power supply voltage.

3. The memory device of claim 2, wherein the wordline voltage control circuit comprises an interconnect resistor connected between the source of the third voltage control transistor and the ground terminal.

4. The memory device of claim 2, wherein the wordline voltage control circuit comprises an interconnect resistor connected between the source of the second voltage control transistor and the second node.

5. The memory device of claim 2, wherein the wordline voltage control circuit comprises an interconnect resistor connected between the first node and the drain of the second voltage control transistor.

6. The memory device of claim 5, wherein the interconnect resistor is configured to be formed by a via contact connected to a portion of a plurality of ground metal lines.

7. The memory device of claim 5, wherein a magnitude of the wordline driving voltage is based on a resistance value of the interconnect resistor and based on an increase of the power supply voltage.

8. The memory device of claim 5, wherein a magnitude of the wordline driving voltage is based on an effective resistance of the first voltage control transistor and based on a decrease of the power supply voltage.

9. The memory device of claim 2,
wherein the first voltage control transistor comprises a P-type transistor, and
wherein the second voltage control transistor, the third voltage control transistor, the first bump replica transistor, and the second bump replica transistor comprise an N-type transistor.

10. A memory device comprising:
a memory cell array including a plurality of memory cells;
a row decoder configured to select one of a plurality of wordlines connected to the plurality of memory cells based on an address received from a memory controller; and
a wordline voltage generator configured to provide a wordline voltage to the selected one of the plurality of wordlines,
wherein the wordline voltage generator comprises:
a wordline driver configured to output the wordline voltage, the wordline voltage being configured to be reduced by a power supply voltage, the power supply voltage being configured to vary based on a wordline driving voltage;
a first voltage control transistor including a source configured to receive the power supply voltage, a drain connected to a first node configured to output the wordline driving voltage, and a gate configured to receive a bump signal;
a second voltage control transistor including a drain connected to the first node, a source connected to a second node, and a gate configured to receive a voltage adjustment enable signal;
a third voltage control transistor including a drain and a gate connected to the second node, and a source connected to a third node;
an interconnect resistor connected between the third node and a ground terminal;
a first bump replica transistor including a drain configured to receive the power supply voltage, a source connected to a fourth node configured to output the bump signal, and a gate configured to receive the voltage adjustment enable signal; and
a second bump replica transistor including a drain connected to the fourth node, a source connected to the ground terminal, and a gate configured to receive the power supply voltage.

11. The memory device of claim 10, wherein a magnitude of the wordline driving voltage is based on a resistance value of the interconnect resistor based on an increase of the power supply voltage.

12. The memory device of claim 10, wherein a magnitude of the wordline driving voltage is based on an effective resistance of the first voltage control transistor based on a decrease of the power supply voltage.

13. The memory device of claim 10, wherein the interconnect resistor is connected to a portion of a plurality of ground metal lines by a via contact.

14. The memory device of claim 10,
wherein the first voltage control transistor comprises a P-type transistor, and
wherein the second voltage control transistor, the third voltage control transistor, the first bump replica transistor, and the second bump replica transistor comprise an N-type transistor.

15. A memory device comprising:
a memory cell array including a plurality of memory cells configured to operate at a first power supply voltage;
an input/output circuit configured to operate at a second power supply voltage lower than the first power supply voltage and perform a read or write operation of data through a plurality of bitlines connected to the plurality of memory cells;
a row decoder configured to select one of a plurality of wordlines connected to the plurality of memory cells based on an address received from a memory controller; and
a wordline voltage generator configured to provide a wordline voltage to the selected one of the plurality of wordlines,
wherein the wordline voltage generator comprises:
a wordline driver configured to output the wordline voltage, the wordline voltage being configured to be reduced by a power supply voltage, the power supply voltage being configured to vary based on a wordline driving voltage;
a bump replica circuit configured to generate a bump signal, the bump signal being configured to have a voltage level that increases or decreases based on a difference between the first power supply voltage and the second power supply voltage; and
a wordline voltage control circuit configured to output the wordline driving voltage that increases or decreases complementarily to the bump signal based on the first power supply voltage.

16. The memory device of claim 15,
wherein the wordline voltage control circuit comprises:
a first voltage control transistor including a source configured to receive the first power supply voltage, a drain connected to a first node configured to output the wordline driving voltage, and a gate configured to receive the bump signal;
a second voltage control transistor including a drain connected to the first node, a source connected to a second node, and a gate configured to receive a voltage adjustment enable signal; and
a third voltage control transistor including a drain and a gate connected to the second node, and a source connected to a ground terminal, and
wherein the bump replica circuit comprises:
a first bump replica transistor including a drain configured to receive the first power supply voltage, a source connected to a third node configured to output the bump signal, and a gate configured to receive the voltage adjustment enable signal; and
a second bump replica transistor including a drain connected to the third node, a source connected to the ground terminal, and a gate connected to the second power supply voltage.

17. The memory device of claim 16, wherein the wordline voltage control circuit comprises an interconnect resistor connected between the source of the third voltage control transistor and the ground terminal.

18. The memory device of claim 15, wherein the wordline voltage control circuit comprises:
a first voltage control transistor including a source configured to receive the first power supply voltage, a drain connected to a first node configured to output the wordline driving voltage, and a gate configured to receive the bump signal;
a second voltage control transistor including a drain connected to the first node, a source connected to a second node, and a gate configured to receive a voltage adjustment enable signal;
a third voltage control transistor including a drain and a gate connected to the second node, and a source connected to a ground terminal,
wherein the bump replica circuit comprises:
a first bump replica transistor including a drain connected to the second power supply voltage, a source connected to a third node configured to output the bump signal, and a gate configured to receive the voltage adjustment enable signal; and
a second bump control transistor including a drain connected to the third node, a source connected to the ground terminal, and a gate connected to a fourth node, and
wherein a bump control circuit is configured to control a voltage level of the fourth node based on a difference between the first power supply voltage and the second power supply voltage.

19. The memory device of claim 18, wherein the bump control circuit comprises:
a first bump control transistor including a source configured to receive the first power supply voltage, a drain connected to the fourth node, and a gate connected to the third node; and
a second bump control transistor including a source configured to receive the second power supply voltage, a drain connected to the fourth node, and a gate configured to receive the voltage adjustment enable signal.

20. The memory device of claim 19,
wherein the first bump control transistor comprises a P-type transistor, and
wherein the second bump control transistor comprises an N-type transistor.
